(19) United States
(12) Patent Application Publication
(10) Pub. No.: US 2010/0060494 A1
(43) Pub. Date: Mar. 11, 2010

(54) Analog to Digital Converter

(75) Inventor: Trond Jarle Pedersen, Sjetnemarka (NO)

Correspondence Address: FISH & RICHARDSON P.C., PO BOX 1022, MINNEAPOLIS, MN, 55440-1022, US

(73) Assignee: ATMEL Corporation, San Jose, CA (US)

(21) Appl. No.: 12/207,395

(22) Filed: Sep. 9, 2008

(51) Int. Cl. H03M 1/00; H03M 1/12

(52) U.S. Cl. 341/110; 341/155; 341/122

(57) ABSTRACT

An analog to digital converter (ADC) can operate in an amplifier configuration or a converter configuration. In the amplifier configuration, the ADC receives an input voltage and scales the input voltage by a factor during at least one clock cycle. In the converter configuration, the ADC uses the scaled input voltage to determine a digital value corresponding to the input voltage.

### TECHNICAL FIELD

This specification generally relates to electrical circuits.

### BACKGROUND

An analog to digital converter (ADC) converts analog input signals to digital values. Some common ADCs include flash ADCs, successive approximation ADCs, and pipeline ADCs. In some ADC systems, the analog input signal is amplified by a programmable gain amplifier (PGA) before it is converted to digital values. The PGA increases the size of those ADC systems. Furthermore, the PGA increases power consumption in those ADC systems.

### SUMMARY

An ADC can operate in an amplifier configuration or a converter configuration. In the amplifier configuration, the ADC receives an input voltage and scales the input voltage by a factor during at least one clock cycle. In the converter configuration, the ADC uses the scaled input voltage to determine a digital value corresponding to the input voltage.

Particular embodiments of the subject matter described in this specification can be implemented to realize one or more of the following advantages: (i) an ADC system can be implemented without a PGA, thus saving area and reducing power consumption; (ii) an ADC can operate in an amplifier configuration and amplify an input signal; and (iii) an ADC can operate in a converter configuration to convert an analog input signal to a digital value. Amplification is useful, for example, to boost the signal to noise ratio of the input signal, or to boost the analog input signal so that it is closer to a reference voltage, thus allowing use of the full range of an ADC.

The details of one or more embodiments of the subject matter described in this specification are set forth in the accompanying drawings and the description below. Other features, aspects, and advantages of the subject matter will become apparent from the description, the drawings, and the claims.

### DESCRIPTION OF DRAWINGS

FIG. 1 is a conceptual block diagram of an example ADC system.

FIG. 2 is a schematic diagram of an example pipelined ADC system.

FIG. 3 illustrates diagrams for timing and voltage levels of the pipelined ADC system of FIG. 2.

Like reference symbols in the various drawings indicate like elements.

### DETAILED DESCRIPTION

### Example ADC Overview

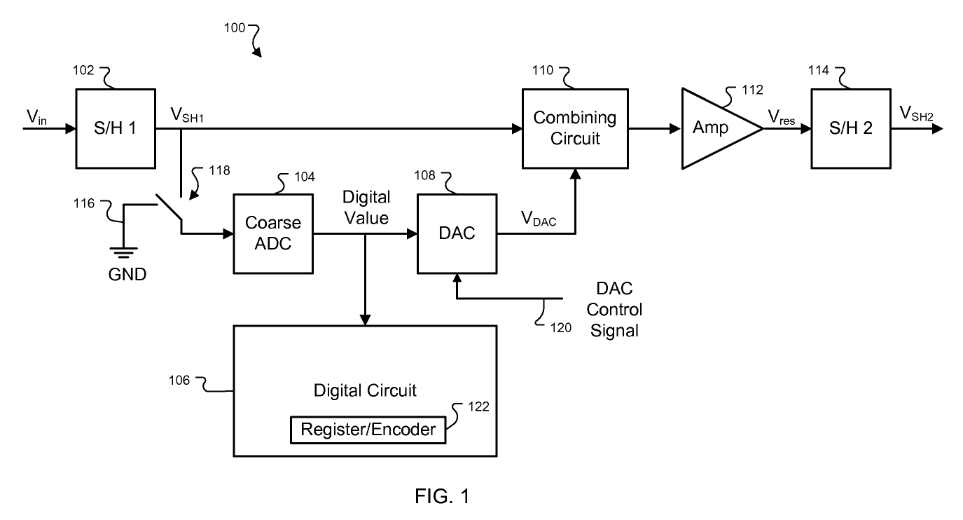

FIG. 1 is a conceptual block diagram of an example analog to digital converter (ADC) system 100. In some implementations, ADC system 100 can include first sample-and-hold (S/H) circuit 102, coarse ADC 104, digital circuit 106, digital to analog converter 108, combining circuit 110, amplifier 112 and second S/H circuit 114.

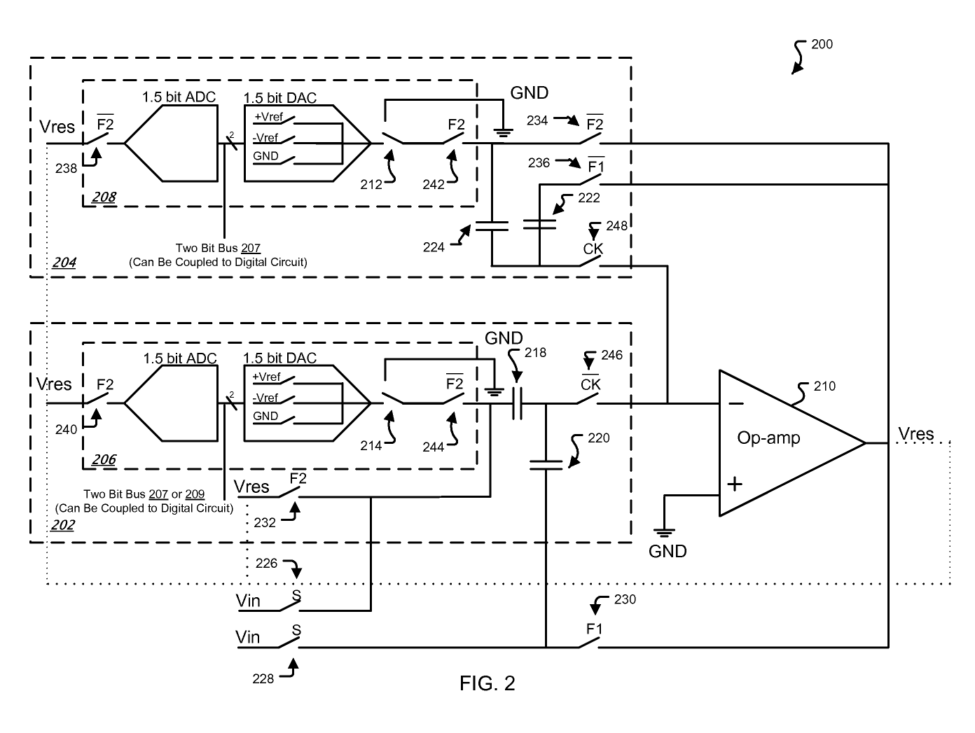

ADC system 100 can stand alone or it can be one stage in a series of stages. For example, ADC system 100 can be one stage of a pipeline ADC. Pipeline ADCs typically have a series of stages that are separated by S/H circuits. The first stage in the ADC pipeline operates on the most recent sample of the analog input voltage, Vᵢₙ, while later stages operate on analog residue voltages Vᵣₑₛ, as described in reference to FIG. 2. In the example configuration of FIG. 1, the analog residue voltage, Vᵣₑₛ, is input to second S/H circuit 114 which can be the input of a second stage of an ADC pipeline.

In some implementations, ADC system 100 can be configured in an amplifier configuration or a converter configuration using, for example, switch 118. When ADC system 100 is in a converter configuration, switch 118 couples a first S/H circuit 102 to coarse ADC 104, and ADC system 100 converts a sample of analog input voltage, V_{in,} into a digital value which can be stored in, for example, a register/encoder 122 of digital circuit 106. When ADC system 100 is in an amplifier configuration, switch 118 couples a ground node 116 to coarse ADC 104 (to bypass coarse ADC 104), and amplifier 112 amplifies (for example, multiplies by a factor of two) the analog input voltage Vᵢₙ.

In some implementations, a digital control signal 120 instructs DAC 108 to output a ground signal regardless of the digital value input to the DAC 108. In the amplifier configuration, ADC system 100 is configured so that combining circuit 110 outputs the held sample of S/H circuit 102, V_{SII1}, which is amplified by amplifier 112.

### Example ADC Structure

The first S/H circuit 102 samples the analog input voltage, V_{in,} and provides a voltage sample V_{SH1}. In some implementations, S/H circuit 102 includes one or more capacitors that can be configured to hold the sampled voltage, V_{SH1}, so that it can be converted to a digital value by the coarse ADC 104, as described in reference to FIG. 2.

Coarse ADC 104 can have a lower resolution than ADC system 100 and thus produce a digital value that comprises fewer bits or has less precision than a digital value produced by ADC system 100. For example, if ADC system 100 provides 8-bit digital values, coarse ADC 104 may provide 2-bit digital values or resolve 1 bit in an 8 bit digital value. In some implementations, coarse ADC 104 is a flash ADC. In other implementations, coarse ADC 104 includes one or more comparators that are configured for comparing an input voltage to a reference voltage. In further implementations, coarse ADC 104 is another type of ADC, for example, a successive approximation ADC or a pipeline ADC.

The output of coarse ADC 104 is coupled to digital circuit 106. Digital circuit 106 can include, for example, a register, or an encoder and a register 122. In some implementations, coarse ADC 104 comprises one or more comparators that compare their inputs (e.g., held sample voltage V_{SH1}) to a reference voltage, and digital circuit 106 determines one or more bits of the output digital value of ADC system 100 based on the comparisons.

Digital circuit 106 can hold the output digital value (e.g., held in register 122). Digital circuit 106 can include logic that uses the digital value, or it can include a microprocessor, or it can be coupled to a microprocessor that uses the digital value. In some implementations, digital circuit 106 performs error correction.

In some implementations, the output of coarse ADC 104 (the digital value) is provided as input to DAC 108. DAC 108 can have the same resolution as coarse ADC 104 or a different resolution. Various implementations of DAC 108, including various resolutions or configurations are possible.

The output of DAC 108, V_{DAC}, is coupled to combining circuit 110. S/H circuit 102 is also coupled to combining circuit 110. Combining circuit 110 can be configured to sum or difference input signals. For example, the output of combining circuit 110 can be the sum or difference between V_{SH1} and V_{DAC} or Vᵣₑₛ=A(V_{SH1}−V_{DAC}) where A is a gain provided by amplifier 112.

The output of combining circuit 110 is coupled to amplifier 112. Amplifier 112 can be, for example, an operational amplifier that scales its input by a gain factor (e.g., a gain factor of two). In general, the gain factor can be selected based on the resolution of ADC system 100. Amplifier 112 outputs a residue voltage Vᵣₑₛ which can be coupled to second S/H circuit 114. In some implementations, second S/H circuit 114 can be coupled to another stage of and ADC pipeline. For example, the other stage can include another coarse ADC, DAC, and combining circuit. In other implementations, second S/H circuit 114 can be coupled to coarse ADC 104, and a digital control signal (for example, a clock signal) determines whether coarse ADC 104 uses the held sample, V_{SH1}, of first S/H circuit 102 or the held sample, V_{SH2}, of second S/H circuit 114. Various other configurations are possible. ADC system 100 is advantageous in that the system 100 divides an analog-to-digital conversion task into several consecutive stages, namely, a sample and hold stage, followed by one or more pipeline stages. Referring to FIG. 1, the first S/H circuit 102 samples and holds the analog input voltage Vᵢₙ. The first S/H circuit 102 is followed by a first pipelined stage which, in this example, includes coarse ADC 104, digital circuit 106, DAC 108, combining circuit 110 and amplifier 112. The pipelined stage produces a digital value (an estimate) of the analog held voltage V_{SII1} at the input of the stage. After the digital value is calculated by the coarse ADC 104, the digital value is converted back to an analog waveform, V_{DAC}, and subtracted from the analog held signal, V_{SH1}, received at the input of the first pipelined stage. The result of the subtraction is referred to as residue voltage. The residue voltage, Vᵣₑₛ, can be amplified by amplifier 112 in a hold phase (e.g., for one or more clock cycles) and supplied to the pipeline stage through second S/H circuit 114 to be sampled and converted in an identical manner.

### Example ADC Operation in Amplifier Configuration

When ADC system 100 is in an amplifier configuration (switch 108 is connected to ground 116), combining circuit 110 outputs the held sample V_{SH1} of first S/H circuit 102, and amplifier 112 amplifies that sample. For example, where the ADC system 100 holds the analog input voltage, Vᵢₙ, and the amplifier 112 scales the held voltage, V_{SH1}, by a gain factor, the residue voltage, Vᵣₑₛ, has the magnitude of the analog input voltage, Vᵢₙ, scaled by the gain factor of the amplifier 112. By coupling the residue voltage, V_{res,} to another stage (e.g., through second S/H circuit 114) or recycling Vᵣₑₛ back into combining circuit 110, the scaling can be repeated. For example, if the gain factor of the amplifier 112 is “A” and the scaling is repeated “x” times, then the ADC system 100 can scale or amplify the analog input voltage, Vᵢₙ, by A^{x}.

### Example ADC Operation in Converter Configuration

When ADC system 100 is in a converter configuration (switch 118 is connected to the output of S/H circuit 102), the sample held by first S/H 102, V_{SH1,} is converted to a coarse digital value by coarse ADC 104. DAC 108 converts the coarse digital value to an analog voltage V_{DAC}. Combining circuit 110 combines the output of DAC 108, V_{DAC}, with the sample voltage, V_{SH1}, held by first S/H circuit 102. Amplifier 112 amplifies the output of combining circuit 110 to produce an amplified residue voltage Vᵣₑₛ. In some implementations, Vᵣₑₛ is passed to another stage in a pipelined ADC. In other implementations, Vᵣₑₛ is recycled through coarse ADC 104, DAC 108, combining circuit 110, and amplifier 112.

### Example Circuit Implementation

FIG. 2 is a schematic diagram of an example ADC system 200. Example ADC system 200 has a similar architecture to ADC system 100 but includes two 1.5 bit pipeline stages 202 and 204 and uses redundant sign decoding rather than the single stage of ADC system 100. A 1.5 bit pipeline stage generates 1 bit of a digital value. In general, a 1.5 bit pipeline stage uses two analog comparison levels, and digital error correction can be used to eliminate the redundancy.

In this example configuration, stages 202 and 204 include capacitors 218, 220 and 222, and 224, respectively. Capacitors 218 and 220 can perform a sample-and-hold function for stage 202, and capacitors 222 and 224 can perform a sample-and-hold function for stage 204. Stages 202 and 204 also include comparator circuits 206 and 208. In this example configuration, comparator circuits 206 and 208 each include a 1.5 bit ADC and a 1.5 bit DAC. In comparator circuit 208, the 1.5 bit ADC and the 1.5 bit DAC are each coupled to a two bit bus 207. The two bit bus 207 can be coupled to a digital circuit (not shown). In some implementations, the digital circuit (e.g., digital circuit 106) performs error correction and provides a digital output to a microprocessor (not shown). In some implementations, comparator circuit 206 can be coupled to the same two bit bus 207 as comparator circuit 208, or to a different two bit bus 209.

ADC system 200 can include operational amplifier (op-amp) 210 which functions in a similar manner to amplifier 112 of FIG. 1, including performing analog multiplication. In some implementations, op-amp 210 outputs a voltage equal to twice its input, thus scaling the analog input voltage, Vᵢₙ, by a gain factor of two. Op-amp 210 outputs a residue voltage, Vᵣₑₛ.

In some implementations, the output of op-amp 210, Vᵣₑₛ, can be coupled to capacitors 218 and 220 by switches 232 and 230. Switch 232 operates according to a control signal “feedback 2” or “F2.” Switch 230 operates according to a control signal “feedback 1” or “F1.” In general, a digital circuit (e.g., digital circuit 106) or a microprocessor provides the control signals F1 and F2 and an inverter or other logic device can provide their complements F̅1̅ and F̅2̅. Thus Vᵣₑₛ can be sampled and held by capacitors 218 and 220 in stage 202.

The output of op-amp 210, Vᵣₑₛ, is also coupled to capacitors 222 and 224 by switches 234 and 236. Switch 234 operates according to control signal F̅2̅ (the complement of F2), so that when switch 232 is open, switch 234 is closed, and when switch 232 is closed, switch 234 is open. Similarly, switch 236 operates according to control signal F̅1̅ (the complement of F1), so that when switch 230 is closed, switch 236 opens. Thus Vᵣₑₛ can be sampled and held by capacitors 222 and 224 in stage 204.

The output of op-amp 210, Vᵣₑₛ, can be further coupled to comparator circuits 206 and 208 through switches 240 and 238. Switch 240 operates (open or closes) according to control signal F2, and switch 238 operates according to control signal F̅2̅.

Switch 242 couples comparator circuit 208 to capacitor 224. Switch 242 operates according to control signal F2. Similarly, switch 244 couples comparator circuit comparator circuit 206 to capacitor 218. Switch 244 operates according to control signal F̅2̅.

ADC system 200 can include switches 212 and 214. When switches 212 and 214 are coupled to ground nodes, ADC system 200 operates in an amplifier configuration. When switches 212 and 214 are coupled to the 1.5 bit DACs of comparator circuits 208 and 206, respectively, ADC system 200 operates in a converter configuration, as described in reference to FIG. 1

### Example Circuit Operation

ADC system 200 converts analog input signals (e.g., Vᵢₙ) into digital values which can be stored in a register of a digital circuit (e.g., register 122 of digital circuit 106). ADC system 200 can first operate in an amplifier configuration and amplifies an input sample (e.g., V_{SH1}). Then ADC system 200 operates in a converter configuration and converts the amplified input sample into a digital value.

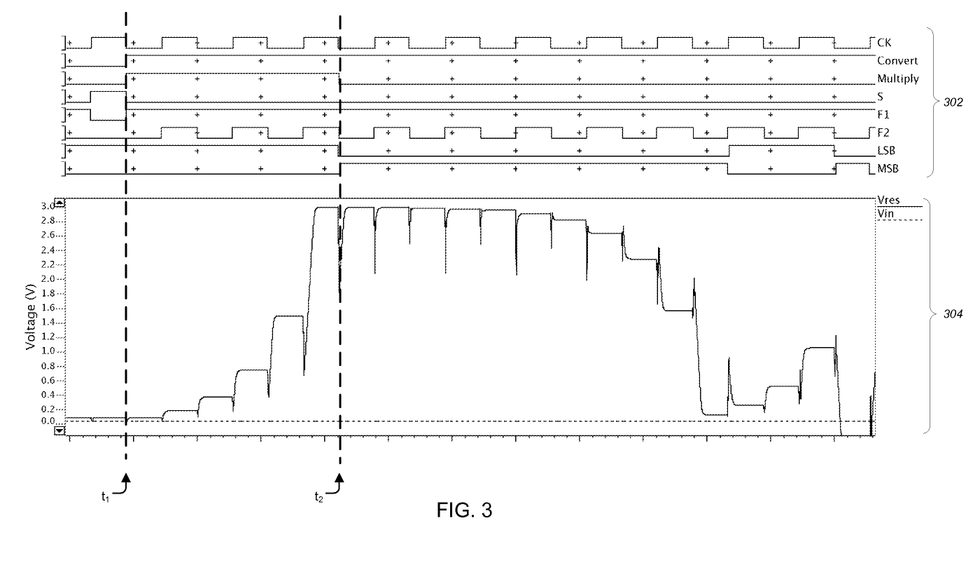

To configure ADC system 200 to an amplifier configuration, switches 212 and 214 can be coupled to ground nodes. Then switches 226 and 228 can be closed according to a control signal “S,” provided by a digital circuit (e.g., digital circuit 106). When control signal F1 falls low (see FIG. 3), switch 230 opens, switch 236 closes, capacitors 218 and 220 sample and hold the input voltage, Vᵢₙ, in stage 202, and switches 226 and 228 open.

Switch 246 closes when a clock signal falls low (see FIG. 3). Control signal, F1, rises high, and switch 230 closes and switch 236 opens. Op-amp 210 performs a multiply by two and produces a residue voltage, Vᵣₑₛ. In general, Vᵣₑₛ can be calculated as follows:

$$\begin{matrix}{V}_{res} = 2 \cdot {V}_{i n} \\ = ( 1 + \frac{{C}_{s}}{{C}_{f}} ) \cdot {V}_{i n} \\ = {E}_{Gain} \cdot ( 1 + \frac{{C}_{s} + {C}_{mismatch}}{{C}_{f}} ) \\ = {E}_{Gain} ( 2 + \frac{{C}_{mismatch}}{{C}_{f}} )\end{matrix} \qquad [ 1 ]$$

In [1], E_{Gain} is gain error caused by finite DC/gain and C_{mismatch} is capacitor mismatch between the capacitors 218, 220, 22, 224. Using capacitor trimming and a high gain op-amp minimizes the resulting error.

The residue voltage, Vᵣₑₛ, can be sampled at capacitors 222 and 224. By closing switch 248, op-amp 210 can perform its multiplication by two again during another clock cycle. The multiplication can be repeated to achieve a desired level of amplification, as shown in FIG. 3 for 5 iterations

Redundant sign decoding can reduce the number of necessary circuit elements. For example, in the example configuration shown, op-amp 210 is coupled to a first sample-and-hold circuit (formed by capacitors 222, 224) and a second sample-and-hold circuit (formed by capacitors 218, 220), so that during a first clock phase (resulting in switch 248 being closed and switch 246 being opened) op-amp 210 sees the voltage held in the first sample-and-hold circuit and during a second clock phase (resulting in switch 248 being opened and switch 246 being closed) op-amp 210 sees the voltage held in the second sample-and hold circuit.

When the desired amplification is achieved, switches 212 and 214 are coupled to the 1.5 bit DACs of comparator circuits 208 and 206, respectively. This places ADC system 200 into a converter configuration. During one or more clock cycles, the output, V_{res,} of op-amp 210 is coupled to comparator circuit 208 (through switches 234, 236). During other clock cycles, the output, V_{res,} of op-amp 210 is coupled to comparator circuit 206 (through switch 230).

In some implementations, when ADC system 200 is in a converter configuration, it generally has the following transfer function:

$${V}_{res} = \{ \begin{matrix}2 \cdot {V}_{i n} - {V}_{ref} & if {V}_{i n} > \frac{1}{4} {V}_{ref} \\ 2 \cdot {V}_{i n} & if - \frac{1}{4} {V}_{ref} \leq {V}_{i n} \leq \frac{1}{4} {V}_{ref} \\ 2 \cdot {V}_{i n} + {V}_{ref} & if {V}_{i n} < - \frac{1}{4} {V}_{ref}\end{matrix} \qquad [ 2 ]$$

In [2], V_{ref} is a reference voltage used in the 1.5 bit DACs and Vᵢₙ is the analog input signal.

### Example Timing Diagram

FIG. 3 is a timing diagram for an example ADC, for example, ADC system 200. FIG. 3 shows several digital signals 302 and two analog voltage levels 304 above a horizontal timeline. FIG. 3 shows an example of an ADC first amplifying an input sample (e.g., V_{SH1}) and then converting the input sample into a digital value.

Some of the digital signals 302 are control signals, including a clock signal, CK; a signal to activate the ADC, Convert; a signal that determines whether the ADC is in an amplifier mode or a convert mode, Multiply; a signal to open a sampling switch, S; a first feedback control signal, F1; and a second feedback control signal, F2. Some of the digital signals 302 are output digital values, including a least significant bit, LSB; and a most significant bit, MSB. The analog voltage levels 304 include Vᵢₙ, a voltage of an analog input signal, and Vᵣₑₛ, a residue voltage (for example, the output of op-amp 210).

Referring now to FIG. 3 with reference to FIG. 2, at time t₁, control signals Convert and Multiply rise. When Multiply rises, the ADC is in an amplifier configuration. The ADC multiplies an input sample by two during clock cycles where Convert and Multiply are high. At time t₂, control signal Multiply falls. When Multiply falls, the ADC is in a converter configuration.

Between times t₁ and t₂, the ADC multiplies the input sample by two five times, as indicated by the five voltage steps in Vᵣₑₛ between t₁ and t₂). The solid line representing Vᵣₑₛ in the analog voltage levels 304 demonstrates the result of each multiplication.

After time t₂, the ADC converts the resulting Vᵣₑₛ into a digital value. The digital value is represented by digital signals LSB and MSB (assuming a two-bit digital value), which can be stored in a digital circuit, for example, register 122 in digital circuit 106 of FIG. 1. LSB refers to a digital signal (e.g., 0 or 1) representing the least significant bit of the digital value and MSB refers to a digital signal (0 or 1) representing the most significant bit of the digital value.

A number of implementations of the invention have been described. Nevertheless, it will be understood that various modifications may be made without departing from the spirit and scope of the invention. For example, although implementations of the invention have been shown and described in terms of single-ended circuitry, those of skill in the art will recognize that differential circuitry can also be used. For example, the op-amp 210 in FIG. 2 could be replaced with a differential amplifier as well as additional wiring to carry the differential signals. Accordingly, other implementations are within the scope of the following claims where each claim can be a separate embodiment and combinations of different claims can be separate embodiments.

What is claimed is:

1. An analog to digital converter (ADC) comprising a circuit operable in an amplifier configuration or a converter configuration, where:
in the amplifier configuration, the ADC receives an input voltage and scales the input voltage by a factor during at least one clock cycle; and
in the converter configuration, the ADC uses the scaled input voltage to determine a digital value corresponding to the input voltage.

2. The ADC of claim 1, where the circuit comprises:
a first sample-and-hold circuit operable to sample the input voltage;
a coarse ADC coupled to the first sample-and-hold circuit and operable to convert the sampled input voltage to an intermediate digital value, where the coarse ADC has a lower resolution than the ADC;
a digital to analog converter (DAC) coupled to the coarse ADC and operable to convert the intermediate digital value to an intermediate analog value;
an amplifier coupled to the first sample-and-hold circuit, where the amplifier is operable to multiply the sampled input voltage by the factor; and
a combining circuit coupled to the amplifier, where the combining circuit is operable to combine the multiplied sampled input voltage with the intermediate analog value to output a residue voltage.

3. The ADC of claim 2, where:
the residue voltage output by the combining circuit is coupled to a second sample-and-hold circuit; and
the second sample-and-hold circuit is coupled to the amplifier or the combining circuit.

4. The ADC of claim 3, where in the amplifier configuration:
at least one of the DAC, the coarse ADC, and the combining circuit is coupled to a ground node, so that the intermediate analog voltage seen by the combining circuit is ground.

5. The ADC of claim 3, where in the converter configuration:
the second sample-and-hold circuit is coupled to the coarse ADC.

6. The ADC of claim 2, where:
the first sample-and-hold circuit comprises one or more capacitors;
the amplifier comprises an operational amplifier; and
the combining circuit is a summation or subtraction circuit.

7. The ADC of claim 2, where the coarse ADC comprises:
one or more comparators coupled to a reference voltage and a digital circuit, where the comparators compare the reference voltage and the sampled input voltage.

8. The ADC of claim 7 where the digital circuit is an encoder.

9. The ADC of claim 1 where the circuit comprises:
a pipeline stage comprising one or more digital to analog converters (DACs); and
an amplifier coupled to a first sample-and-hold circuit and a second sample-and-hold circuit so that during a first clock phase the amplifier sees the voltage held in the first sample-and-hold circuit and during a second clock phase the amplifier sees the voltage held in the second sample-and hold circuit.

10. The ADC of claim 9 where:
in the amplifier configuration, the DACs are bypassed.
